(19) United States
(12) Patent Application Publication
(10) Pub. No.: US 2010/0024867 A1
(43) Pub. Date: Feb. 4, 2010

(54) GEODESIC DOME PHOTOVOLTAIC CELL POWER SYSTEM

(76) Inventor: Wardell GILLESPIE, (US)

Correspondence Address: LADAS & PARRY LLP, 224 SOUTH MICHIGAN AVENUE, SUITE 1600, CHICAGO, IL, 60604, US

(21) Appl. No.: 12/183,253

(22) Filed: Jul. 31, 2008

(51) Int. Cl. H01L 31/042

(52) U.S. Cl. 136/246

(57) ABSTRACT

A geodesic dome photovoltaic cell power system is presented which provides a number of major advantages over more conventional systems. The system recovers and recycles energy from the sunlight, standard AC lighting, and batteries as well. The system provides electrical service whether or not sunlight is available. The system provides a way of returning some used energy back into the system for reuse. The system also provides a way of sending light to rooms below the geodesic dome shape of the system. The system gathers significantly more sunlight than conventional solar flat layouts. The system includes a plurality of trigonal light guides interconnected together that have a plurality of tapered mirrored walls and has an internal solar cell; and a battery. The system can also include optional components such as a plurality of hexagonal light guides, a transformer, a base, an antireflection layer, a plurality of external solar cells, and a plurality of external mirrors.

### FIELD OF THE INVENTION

The present invention relates solar energy conversion. More particularly to a geodesic dome photovoltaic cell power system configured to provide a number of advantages such as converting efficiently solar energy into electrical energy and configured to convey a portion of the sunlight through the device for purposes of illumination.

### BACKGROUND OF THE INVENTION

Presently, fossil fuels provide at least three fourths of all of our energy demands. It is well known that supplies of fossil fuel are finite and limited. Unfortunately when fossil fuels are consumed for energy production then large numbers of environmental pollutants are also produced. Some of these environmental pollutants are thought to be harmful to human health and some are even thought to threaten the global climate itself. In contrast to fossil fuels, sunlight is the most plentiful energy resource on earth. Further, solar energy conversion does not produce pollutants. The problem with solar energy conversion is that there is a need to increase the energy transfer efficiency.

A wide variety of solar energy conversion devices is currently available on the commercial market and an even larger number of these types of devices are known in the art of solar energy conversion devices. While these solar energy conversion devices may fulfill their respective, particular objectives and requirements, no known solar energy conversion device is known to provide a means for recovering and recycling energy from the sunlight, standard AC lighting, and batteries as well. Also no known solar energy conversion device is known to provide a means for providing electrical service whether or not sunlight is available. Further no known solar energy conversion device is known to provide a means for providing a power system that returns some used energy to the system for reuse. Still yet no known solar energy conversion device is known to provide a means for sending light to rooms below the geodesic dome shape of the system. Even yet further no known solar energy conversion device is known to provide a means for gathering significantly more exposure to the sunlight than conventional solar flat layouts.

Therefore, a need exists for a new and improved geodesic dome photovoltaic cell power system that can provide (1) a means for recovering and recycling energy from the sunlight, standard AC lighting, and batteries as well; (2) a means for providing electrical service whether or not sunlight is available; (3) a means for providing a power system that returns some used energy to the system for reuse; (4) a means for sending light to rooms below the geodesic dome shape of the system; (5) a means for gathering significantly more exposure to the sunlight than conventional solar flat layouts; and (6) a means for providing a photovoltaic cell power system that takes up less space than conventional solar flat layouts.

### SUMMARY OF THE INVENTION

The present geodesic dome photovoltaic cell power system, according to the principles of the present invention, overcomes a number of the shortcomings of the prior art by providing a novel geodesic dome photovoltaic cell power system for use in providing (1) a means for recovering and recycling energy from the sunlight, standard AC lighting, and batteries as well; (2) a means for providing electrical service whether or not sunlight is available; (3) a means for providing a power system that returns some used energy to the system for reuse; (4) a means for sending light to rooms below the geodesic dome shape of the system; (5) a means for gathering significantly more exposure to the sunlight than conventional solar flat layouts; and (6) a means for providing a photovoltaic cell power system that takes up less space than conventional solar flat layouts.

In view of the foregoing disadvantages inherent in the known type solar energy conversion devices now present in the prior art, the present invention provides an improved geodesic dome photovoltaic cell power system, which will be described subsequently in great detail, is to provide a new and improved geodesic dome photovoltaic cell power system which is not anticipated, rendered obvious, suggested, or even implied by the prior art, either alone or in any combination thereof.

To attain this the geodesic dome photovoltaic cell power system includes a plurality of trigonal light guides interconnected together that have a plurality of tapered mirrored walls and has an internal solar cell; and a battery. The system can also include optional components such as a plurality of hexagonal light guides, a transformer, a base, an antireflection layer, a plurality of external solar cells, and a plurality of external mirrors. There has thus been outlined, rather broadly, the more important features of the invention in order that the detailed description thereof that follows may be better understood, and in order that the present contribution of the art may be better appreciated.

Numerous aspects, features and advantages of the present invention will be readily apparent to those of ordinary skill in the art upon reading of the following detailed description of presently preferred, but nonetheless illustrative, embodiments of the present invention when taken in conjunction with the accompany drawings. In this respect, before explaining the current embodiment of the invention in detail, it is to be understood that the invention is not limited in its application to the details of construction and to the arrangements of the components set forth in the following description or illustrated in the drawings. The invention is capable of other embodiments and of being practiced and carried out in various ways. Also, it is to be understood that the phraseology and terminology employed herein are for the purpose of description and should not be regarded as limiting.

As such, those skilled in the art will appreciate that the conception, upon which this disclosure is based may readily be utilized as a basis for the designing of other structures, methods and systems for carrying out the several purposes of the present invention. It is important, therefore, that the claims be regarded as including such equivalent constructions insofar as they do not depart from the spirit and scope of the present invention.

It is therefore an aspect of the present invention to provide a new and improved geodesic dome photovoltaic cell power system that has many of the advantages of the prior geodesic dome photovoltaic cell power systems and minimizing a number of their disadvantages.

It is another aspect of the present invention to provide a new and improved geodesic dome photovoltaic cell power system that may be easily and efficiently manufactured and marketed.

An even further aspect of the present invention is to provide a new and improved geodesic dome photovoltaic cell power system that has a low cost of manufacture with regard to both materials and labor, and which accordingly is then susceptible of low prices of sale to the consuming public, thereby making solar energy conversion economically feasible and available to the buying public.

Another aspect of the the present invention is to provide a means for recovering and recycling energy from the sunlight, standard AC lighting, and batteries as well.

Still another aspect of the the present invention is to provide a means for providing electrical service whether or not sunlight is available.

Yet another aspect of the the present invention is to provide a means for providing a power system that returns some used energy to the system for reuse.

Even still yet another aspect of the the present invention is to provide a means for sending light to rooms below the geodesic dome shape of the system.

Still another aspect of the the present invention is to provide a means for gathering significantly more exposure to the sunlight than conventional solar flat layouts.

Yet another aspect of the present invention is to provide a means for providing a photovoltaic cell power system that takes up less space than conventional solar flat layouts.

Even still another aspect of the present invention is to provide a geodesic dome photovoltaic cell power system having a plurality of trigonal light guides, an internal solar cell, and a battery.

There has thus been outlined, rather broadly, the more important features of the invention in order that the detailed description thereof that follows may be better understood, and in order that the present contribution of the art may be better appreciated.

Numerous other features and advantages of the present invention will be readily apparent to those of ordinary skill in the art upon reading of the following detailed description of presently preferred, but nonetheless illustrative, embodiments of the present invention when taken in conjunction with the accompany drawings. In this respect, before explaining the current embodiment of the invention in detail, it is to be understood that the invention is not limited in its application to the details of construction and to the arrangements of the components set forth in the following description or illustrated in the drawings. The invention is capable of other embodiments and of being practiced and carried out in various ways. Also, it is to be understood that the phraseology and terminology employed herein are for the purpose of description and should not be regarded as limiting.

Further, the purpose of the foregoing abstract is to enable the U.S. Patent and Trademark Office and the public generally, and especially the scientist, engineers and practitioners in the art who are not familiar with patent or legal terms or phraseology, to determine quickly from a cursory inspection the nature and essence of the technical disclosure of the application. The abstract is neither intended to define the invention of the application, which is measured by the claims, nor is it intended to be limiting as to the scope of the invention in any way.

These together with other aspects of the invention, along with the various features of novelty that characterize the invention, are pointed out with particularity in the claims annexed to and forming a part of this disclosure. For a better understanding of the invention, its operating advantages and the specific aspects attained by its uses, reference should be had to the accompanying drawings and description matter in which there are illustrated preferred embodiments of the invention.

### BRIEF DESCRIPTION OF THE DRAWINGS

The invention will be better understood and aspects other than those set forth above will become apparent when consideration is given to the following detailed description thereof. Such description makes reference to the annexed drawings wherein:

FIG. 1 is a side view of an embodiment of the geodesic dome photovoltaic cell power system constructed in accordance with the principles of the present invention;

FIG. 2 is a top view of another embodiment of the geodesic dome photovoltaic cell power system of the present invention;

FIG. 3 is a perspective view of an embodiment of the trigonal light guide of the present invention;

FIG. 4 is a perspective view of an embodiment of an optional hexagonal light guide of the present invention; and

FIG. 5 is a top view of an embodiment of the solar energy conversion system of the present invention.

The same reference numerals refer to the same parts throughout the various figures.

### DETAILED DESCRIPTION OF THE PREFERRED EMBODIMENT

The following detailed embodiments presented herein are for illustrative purposes. That is, the detailed discussion herein of one or more embodiments is not intended, nor is to be construed, to limit the metes and bounds of the patent protection afforded the present invention, in which the scope of patent protection is intended to be defined by the claims and their equivalents thereof. Therefore, embodiments not specifically addressed herein, such as adaptations, variations, modifications, and equivalent arrangements, should be and are considered to be implicitly disclosed by the illustrative embodiments and claims described herein and therefore fall within the scope of the present invention.

Further, it should be understood that, although steps of various the claimed method may be shown and described as being in a sequence or temporal order, the steps of any such method are not limited to being carried out in any particular sequence or order, absent an indication otherwise. That is, the claimed method steps are to be considered to be capable of being carried out in any sequential combination or permutation order while still falling within the scope of the present invention.

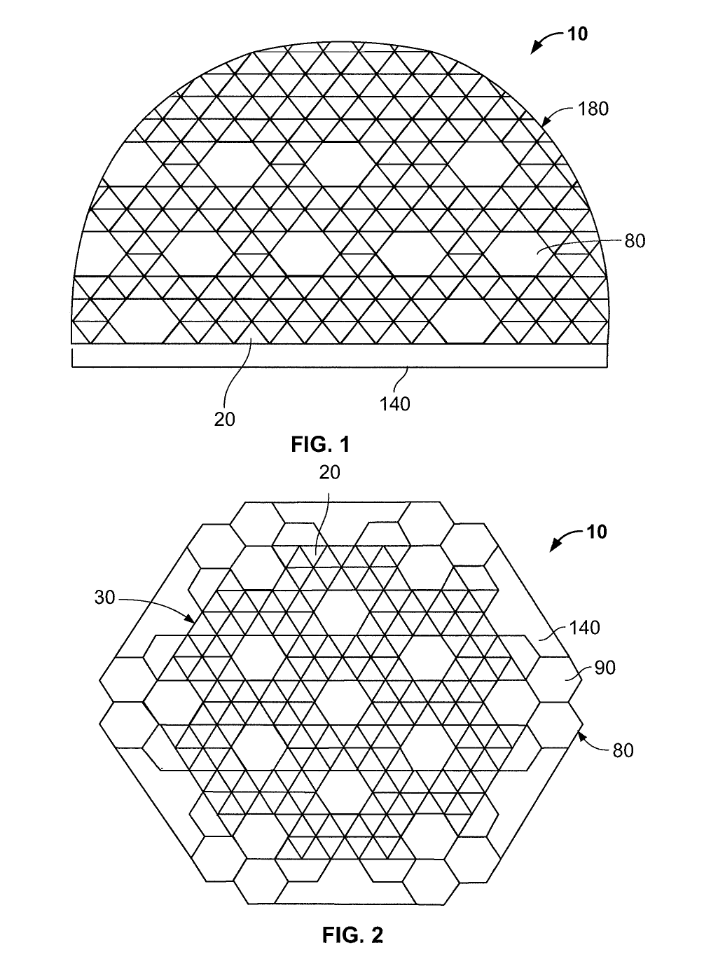

Referring now to the drawings, and in particular FIGS. 1 to 5 thereof, one preferred embodiment of the geodesic dome photovoltaic cell power system 10 comprises: a plurality of trigonal light guides 20 interconnected together, each trigonal light guide 20 comprising: a front triangular surface 30, a rear triangular surface 40, and a plurality of tapered mirrored walls 50 extending between the front triangular surface 30 and the rear triangular surface 40; a plurality of internal solar cells 70, each trigonal light guide 20 having one internal solar cell 70; and a battery 130 electrically connected to each internal solar cell 70.

The battery 130 of the system 10 can be any commercially available battery 130 such as those selected from the group consisting of a nickel-cadmium battery 130, a lead-zinc battery 130, a lithium ion battery 130, a nickel metal hydride battery 130, a zinc-carbon battery 130, a zinc-chloride battery 130, an alkaline/manganese battery 130, and a silver-oxide battery 130 and a metal oxyhydroxide battery 130.

The internal solar cell 70 of the system 10 can be any commercially available internal solar cell 70 such as those selected from the group consisting of monocrystalline silicon (Si) internal solar cell 70, polycrystalline silicon (poly-Si) internal solar cell 70, amorphous silicon (amorp-Si) internal solar cell 70, germanium (Ge) internal solar cell 70, gallium arsenide (GaAs) internal solar cell 70, gallium indium phosphide (GaInP₂) internal solar cell 70, cadmium sulfide (CdS) internal solar cell 70, cadmium selenide (CdSe) internal solar cell 70, cadmium telluride (CdTe) internal solar cell 70 and copper indium selenide (CuInSe₂) internal solar cell 70, titanium oxide (TiO₂) internal solar cell 70, zinc oxide (ZnO) internal solar cell 70, tin oxide (SnO₂) internal solar cell 70, tungsten oxide (WO₂) internal solar cell 70, indium oxide internal solar cell 70, molybdenum disulfide (MoS₂) internal solar cell 70, molybdenum diselenide (MoSe₂) internal solar cell 70, and molybdenum ditelluride (MoTe₂) internal solar cell 70.

An optional plurality of hexagonal light guides 80 may be added to the system 10 in which the plurality of hexagonal light guides 80 are interconnected to the plurality of trigonal light guides 20. Each hexagonal light guide comprising: a front hexangular surface 90, a rear hexangular surface 100, and an untapered body 110 extending between the front hexangular surface 90 and the rear hexangular surface 100. The optional hexagonal light guide is substantially transparent to sunlight 190 and can be composed of any known type of material such as borosilicate glass, quartz, cellulose acetate, cellulose acetate butyrate, cellulose propionate, polyacrylate, polyarylate, amorphous polyamide, polycarbonate, polyetherimide, sulfonated polyether, polyethylene terephthalate, polystyrene, styrene-acrylonitrile copolymer, styrene-maleic anhydride copolymer, polysulfone, polyvinyl chloride and admixtures thereof.

An optional transformer 120 may be added to the system 10 in which the transformer 120 is electrically coupled to the battery 130 in which the transformer 120 is configured to convert direct current (DC) into alternating current (AC).

An optional base 140 may be added to the system 10 in which the base 140 can be a fresnel lens base 140

An optional antireflection layer 150 may be added to the system 10 in which the antireflection layer 150 is attached to the plurality of trigonal light guides 20 and attached to the plurality of hexagonal light guides 80.

An optional plurality of external solar cells 130 may be added to the system 10 in which the external solar cells 130 are electrically connected to the battery 130. The external solar cell 170 can be selected from the group consisting of monocrystalline silicon (Si) external solar cell 170, polycrystalline silicon (poly-Si) external solar cell 170, amorphous silicon (amorp-Si) external solar cell 170, germanium (Ge) external solar cell 170, gallium arsenide (GaAs) external solar cell 170, gallium indium phosphide (GaInP₂) external solar cell 170, cadmium sulfide (CdS) external solar cell 170, cadmium selenide (CdSe) external solar cell 170, cadmium telluride (CdTe) external solar cell 170 and copper indium selenide (CuInSe₂) external solar cell 170, titanium oxide (TiO₂) external solar cell 170, zinc oxide (ZnO) external solar cell 170, tin oxide (SnO₂) external solar cell 170, tungsten oxide (WO₂) external solar cell 170, indium oxide external solar cell 170, molybdenum disulfide (MOS₂) external solar cell 170, molybdenum diselenide (MoSe₂) external solar cell 170, and molybdenum ditelluride (MoTe₂) external solar cell 170.

An optional plurality of external mirrors 160 may be added to the system 10 in which it is preferrable that the external mirrors 160 are curved.

Another embodiment of the geodesic dome photovoltaic cell power system 10 comprises: a plurality of trigonal light guides 20 interconnected together, each trigonal light guide 20 comprising: a front triangular surface 30, a rear triangular surface 40, and a plurality of tapered mirrored walls 50 extending between the front triangular surface 30 and the rear triangular surface 40; a plurality of internal solar cells 70, each trigonal light guide 20 having one internal solar cell 70; a battery 130 electrically connected to each internal solar cell 70; a plurality of hexagonal light guides 80 interconnected to the plurality of trigonal light guides 20, each hexagonal light guide comprising: a front hexangular surface 90, a rear hexangular surface 100, and an untapered body 110 extending between the front hexangular surface 90 and the rear hexangular surface 100; a transformer 120 electrically coupled to the battery 130 wherein the transformer 120 is configured to convert direct current (DC) into alternating current (AC); a plurality of external solar cells 130 electrically connected to the battery 130; and a plurality of external mirrors 160.

Referring now to FIG. 1 which depicts a side view of an geodesic dome photovoltaic cell power system 10 which shows a plurality of trigonal light guides 20 interconnected together, the optional plurality of hexagonal light guides 80 interconnected to the plurality of trigonal light guides 20 and a base 140.

Referring now to FIG. 2 which depicts a top view of another embodiment of the geodesic dome photovoltaic cell power system 10 which shows a plurality of trigonal light guides 20 interconnected together; shows a plurality of the optional hexagonal light guides 80 interconnected to the plurality of trigonal light guides 20; and shows a base 140.

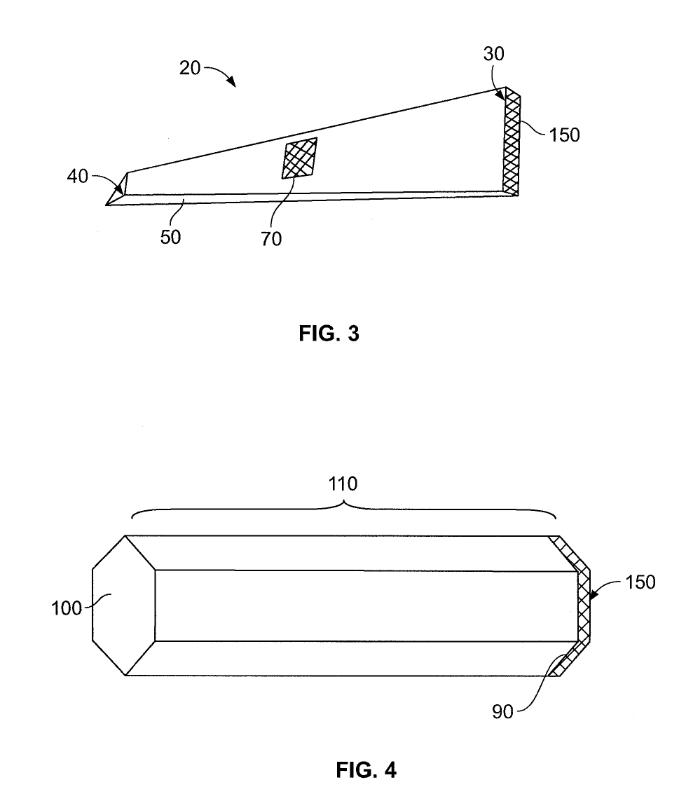

Referring now to FIG. 3 which depicts a perspective side view of one trigonal light guide 20. The trigonal light guide 20 is shown having a front triangular surface 30, a rear triangular surface 40, a plurality of tapered mirrored walls 50 extending between the front triangular surface 30 and the rear triangular surface 40. Also shown is an internal solar cell 70 internally mounted within the trigonal light guide 20. Also shown is a portion of an optional antireflection layer 150 attached to trigonal light guide 20.

Referring now to FIG. 4 which depicts a perspective side one of the optional hexagonal light guides 80. The optional hexagonal light guide is shown comprising: a front hexangular surface 90, a rear hexangular surface 100, and an untapered body 110 extending between the front hexangular surface 90 and the rear hexangular surface 100. Also shown is a portion of an optional antireflection layer 150 attached to hexagonal light guide.

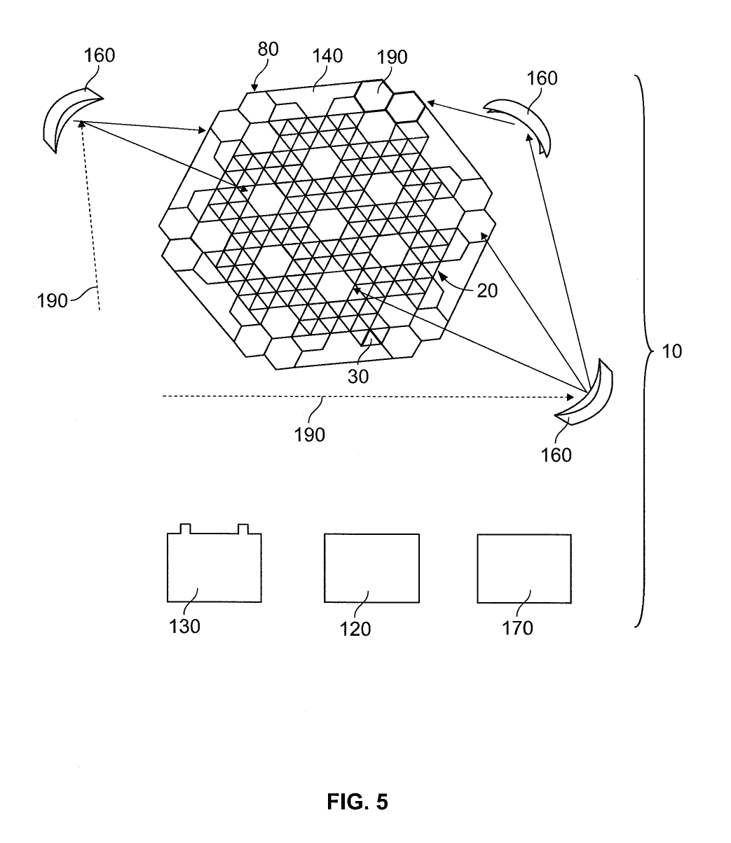

Referring now to FIG. 5 which depicts a view of an embodiment of the geodesic dome photovoltaic cell power system 10 of the present invention. The geodesic dome photovoltaic cell power system 10 is shown comprising: a plurality of external mirrors 160, a transformer 120, and a battery 130. The geodesic dome photovoltaic cell power system 10 is shown comprising a plurality of trigonal light guides 20, a plurality of hexagonal light guides 80 and a base 140. The external mirrors 160 are shown reflecting sunlight 190 onto geodesic dome photovoltaic cell power system 10.

While a number of preferred embodiments of the geodesic dome photovoltaic cell power system, system and method of using same have been described in detail, it should be apparent that modifications and variations thereto are possible, all of which fall within the true spirit and scope of the invention. With respect to the above description then, it is to be realized that the optimum dimensional relationships for the parts of the invention, to include variations in size, materials, shape, form, function and manner of operation, assembly and use, are deemed readily apparent and obvious to one skilled in the art, and all equivalent relationships to those illustrated in the drawings and described in the specification are intended to be encompassed by the present invention.

Those skilled in the art will appreciate that the invention described herein is susceptible to variations and modifications other than those specifically described. It is to be understood that the invention includes all such variations and modification which fall within its spirit and scope. The invention also includes all of the steps, features, compositions and compounds referred to or indicated in this specification, individually or collectively, and any and all combinations of any two or more of said steps or features.

Therefore, the foregoing is considered as illustrative only of the principles of the invention. Further, since numerous modifications and changes will readily occur to those skilled in the art, it is not desired to limit the invention to the exact construction and operation shown and described, and accordingly, all suitable modifications and equivalents may be resorted to, falling within the scope of the invention.

What is claimed is:

1. A geodesic dome photovoltaic cell power system comprising:
a plurality of trigonal light guides interconnected together, each trigonal light guide comprising:
a front triangular surface,
a rear triangular surface, and
a plurality of tapered mirrored walls extending between the front triangular surface and the rear triangular surface;
a plurality of internal solar cells, wherein some trigonal light guides having at least one internal solar cells and other trigonal light guides have no internal solar cells; and
a battery electrically connected to each internal solar cell.

2. The system of claim 1 wherein the system provides a means for recovering and recycling energy from the sunlight, standard AC lighting, and batteries as well.

3. The system of claim 1 wherein the system provides a means for providing electrical service whether or not sunlight is available.

4. The system of claim 1 wherein the system provides a means for providing a power system that returns some used energy to the system for reuse.

5. The system of claim 1 wherein the plurality of trigonal light guides provides a means for sending light to rooms below the geodesic dome shape of the system.

6. The system of claim 1 wherein the system provides a means for gathering significantly more exposure to the sunlight than conventional solar flat layouts.

7. The system of claim 1 wherein the system provides a means for taking up less space than more convention solar energy conversion systems.

8. The system of claim 1 further comprising a plurality of hexagonal light guides interconnected to the plurality of trigonal light guides, each hexagonal light guide comprising:
a front hexangular surface,
a rear hexangular surface, and
an untapered body extending between the front hexangular surface and the rear hexangular surface.

9. The system of claim 1 further comprising a transformer electrically coupled to the battery wherein the transformer is configured to convert direct current (DC) into alternating current (AC).

10. The system of claim 1 further comprising a base.

11. The system of claim 1 further comprising an antireflection layer attached to the plurality of trigonal light guides and attached to the plurality of hexagonal light guides.

12. The system of claim 1 wherein the battery is selected from the group consisting of a nickel-cadmium battery, a lead-zinc battery, a lithium ion battery, a nickel metal hydride battery, a zinc-carbon battery, a zinc-chloride battery, an alkaline/manganese battery, and a silver-oxide battery and a metal oxyhydroxide battery.

13. The system of claim 10 wherein the base is a fresnel lens base.

14. The system of claim 1 wherein the internal solar cell is selected from the group consisting of monocrystalline silicon (Si) internal solar cell, polycrystalline silicon (poly-Si) internal solar cell, amorphous silicon (amorp-Si) internal solar cell, germanium (Ge) internal solar cell, gallium arsenide (GaAs) internal solar cell, gallium indium phosphide (GaInP₂) internal solar cell, cadmium sulfide (CdS) internal solar cell, cadmium selenide (CdSe) internal solar cell, cadmium telluride (CdTe) internal solar cell and copper indium selenide (CuInSe₂) internal solar cell, titanium oxide (TiO₂) internal solar cell, zinc oxide (ZnO) internal solar cell, tin oxide (SnO₂) internal solar cell, tungsten oxide (WO₂) internal solar cell, indium oxide internal solar cell, molybdenum disulfide (MOS₂) internal solar cell, molybdenum diselenide (MoSe₂) internal solar cell, and molybdenum ditelluride (MoTe₂) internal solar cell.

15. The system of claim 1 wherein each hexagonal light guide is composed of a substantially transparent material selected from the group consisting of borosilicate glass, quartz, cellulose acetate, cellulose acetate butyrate, cellulose propionate, polyacrylate, polyarylate, amorphous polyamide, polycarbonate, polyetherimide, sulfonated polyether, polyethylene terephthalate, polystyrene, styrene-acrylonitrile copolymer, styrene-maleic anhydride copolymer, polysulfone, polyvinyl chloride and admixtures thereof.

16. The system of claim 1 further comprising a plurality of external solar cells electrically connected to the battery.

17. The system of claim 1 wherein the external solar cell is selected from the group consisting of monocrystalline silicon (Si) external solar cell, polycrystalline silicon (poly-Si) external solar cell, amorphous silicon (amorp-Si) external solar cell, germanium (Ge) external solar cell, gallium arsenide (GaAs) external solar cell, gallium indium phosphide (GaInP₂) external solar cell, cadmium sulfide (CdS) external solar cell, cadmium selenide (CdSe) external solar cell, cadmium telluride (CdTe) external solar cell and copper indium selenide (CuInSe₂) external solar cell, titanium oxide (TiO₂) external solar cell, zinc oxide (ZnO) external solar cell, tin oxide (SnO₂) external solar cell, tungsten oxide (WO₂) external solar cell, indium oxide external solar cell, molybdenum disulfide (MoS₂) external solar cell, molybdenum diselenide (MoSe₂) external solar cell, and molybdenum ditelluride (MoTe₂) external solar cell.

18. The system of claim 1 further comprising a plurality of external mirrors.

19. The system of claim 18 wherein the external mirrors are curved.

20. A geodesic dome photovoltaic cell power system comprising:
a plurality of trigonal light guides interconnected together, each trigonal light guide comprising:
a front triangular surface,
a rear triangular surface, and
a plurality of tapered mirrored walls extending between the front triangular surface and the rear triangular surface;
a plurality of internal solar cells, wherein some trigonal light guides having at least one internal solar cells and other trigonal light guides have no internal solar cells;
a battery electrically connected to each internal solar cell;
a plurality of hexagonal light guides interconnected to the plurality of trigonal light guides, each hexagonal light guide comprising:
a front hexangular surface,
a rear hexangular surface, and
an untapered body extending between the front hexangular surface and the rear hexangular surface;
a transformer electrically coupled to the battery wherein the transformer is configured to convert direct current (DC) into alternating current (AC);
a plurality of external solar cells electrically connected to the battery; and
a plurality of external mirrors.
